(19) United States
(12) Patent Application Publication
(10) Pub. No.: US 2022/0043026 A1
(43) Pub. Date: Feb. 10, 2022

(54) SOCKET

(71) Applicant: Enplas Corporation, Kawaguchi-shi, Saitama (JP)

(72) Inventor: Yuki Ueyama, Saitama (JP)

(21) Appl. No.: 17/297,004

(22) PCT Filed: Nov. 29, 2019
(86) PCT No.: PCT/JP2019/046695

§ 371 Date: May 26, 2021

(30) Foreign Application Priority Data
Dec. 7, 2018 (JP) 2018-230028

(51) Int. Cl. G01R 1/04

(52) U.S. Cl. CPC G01R 1/0466

(57) ABSTRACT

This socket is provided with: a socket body in which a to-be-inspected member is housed and which also has a to-be-locked part; a cover which is disposed at the upper side of the socket body; and a locking member which is supported by the cover and which has a shaft part extending in the vertical direction and a locking part extending in a direction intersecting with the vertical direction, wherein the cover becomes fixed to the socket body when the locking member is rotated about an axial line thereof and the locking part engages the to-be-locked part.

### TECHNICAL FIELD

The present disclosure relates to a socket used in inspecting electrical characteristics of a component member to be inspected (hereinafter, may also be referred to as “inspected member”).

### BACKGROUND ART

Sockets have been each used for electrically connecting between an inspected member and a wiring board when inspecting the inspected member such as an IC package (e.g., burn-in test).

Patent Literature (hereinafter, referred to as “PTL”) 1 describes a socket including a socket body in which the IC package is placed, a cover provided as a separate body from the socket body, and a latch provided on a cover side and engaging with the socket body, thereby fixing the cover to the socket body.

### CITATION LIST

### Patent Literature

### PTL 1

### Japanese Patent Application Laid-Open No. 2006-252946

### SUMMARY OF INVENTION

### Technical Problem

However, the socket described in PTL 1 involves the following problems because the socket uses a latch in which an engaging portion is provided on its one side.

(1) Since the engaging portion of the latch is provided only on one side of the latch, a large reaction force is applied to the engaging portion of the latch and an engaged portion of the socket body at the time of inspection (i.e., in a state that the cover presses the IC package toward the socket body). Thus, the latch is required to be increased in size and thickness so as to ensure component strength, and the socket body is also required to have a large space for the engaged portion corresponding to the engaging portion of the latch.

(2) Since the engaged portion to be engaged with the engaging portion of the latch is provided on the outer peripheral part of the socket body, an operating space for the latch is necessary further outside the outer peripheral part of the socket body.

An object of the present disclosure is to provide a socket capable of fixing a cover and a socket body without involving an increase in size of the socket.

### Solution to Problem

A socket according to an aspect of the present disclosure includes: a socket body in which an inspected member is housed and which includes a locked portion; a cover placed on an upper side of the socket body; and a locking member which is supported by the cover and includes a shaft portion extending in a vertical direction and a locking portion extending in a direction intersecting the vertical direction, wherein the cover is fixed with respect to the socket body by rotation of the locking member about its own axis to engage with the locked portion.

### Advantageous Effects of Invention

According to the present disclosure, it is possible to fix a cover and a socket body without involving an increase in size of a socket.

### BRIEF DESCRIPTION OF DRAWINGS

FIG. 1 is a perspective view of a socket according to an embodiment;

FIG. 2 is a plan view of the socket according to the embodiment;

FIG. 3A is a cross-sectional view of FIG. 2 taken along a line 3A to 3A;

FIG. 3B is a cross-sectional view of FIG. 2 taken along a line 3B to 3B;

FIG. 3C is a cross-sectional view of FIG. 2 taken along a line 3C to 3C;

FIG. 4 is a perspective view of a locking member;

FIG. 5 is a cross-sectional view of a cover in a state of being fixed to a socket body; and

FIG. 6 is a cross-sectional view of the socket in a state of inspection.

### DESCRIPTION OF EMBODIMENTS

Hereinafter, an embodiment of the present disclosure will be described in detail with reference to the drawings. Note that, the embodiment described below is merely an example, and the present disclosure is not limited by this embodiment. Components of the embodiment described below can also be combined as needed. In some cases, some components may not be used.

For convenience of description, a three-dimensional orthogonal coordinate system composed of the X-axis, Y-axis and Z-axis is illustrated in each figure. It is respectively defined that a positive direction of the X-axis is a +X direction, s positive direction of the Y-axis is a +Y direction, and a positive direction of the Z-axis is a +Z direction (upward direction).

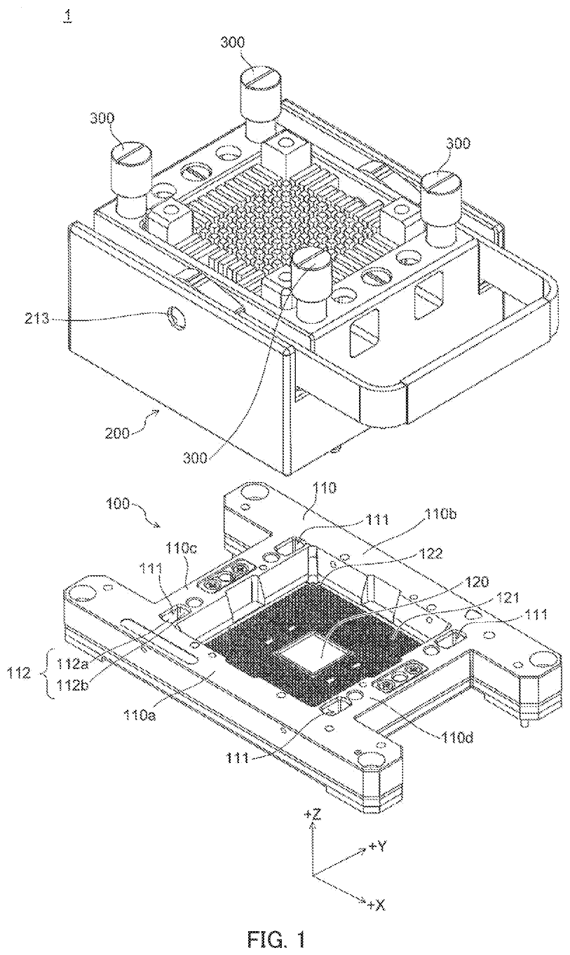

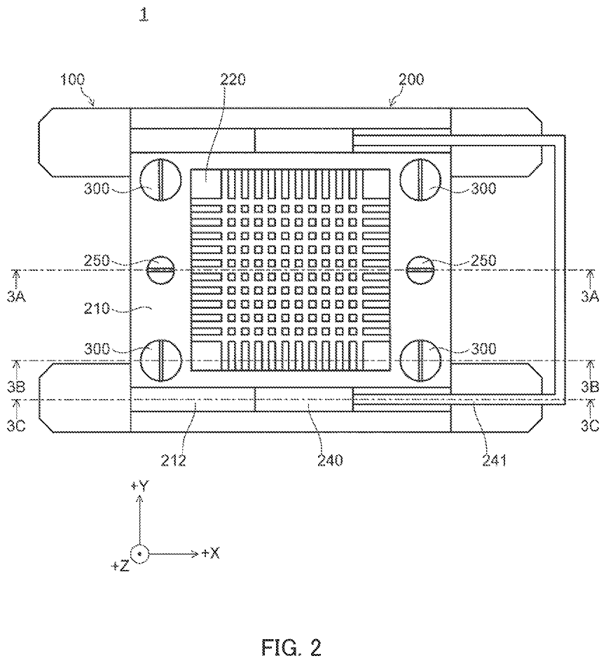

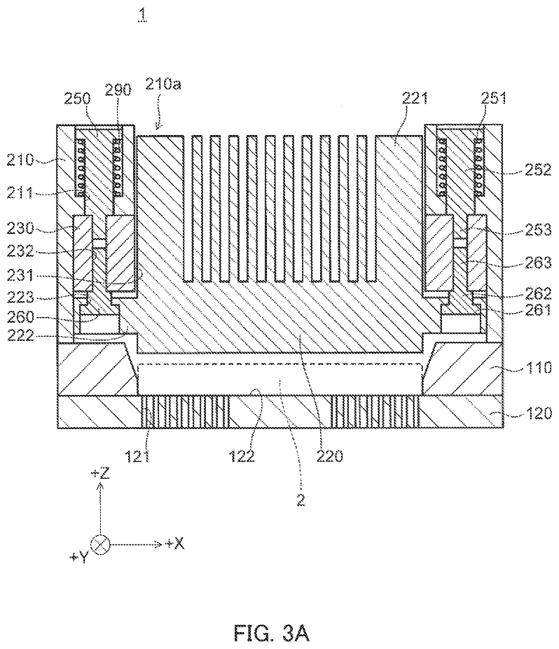

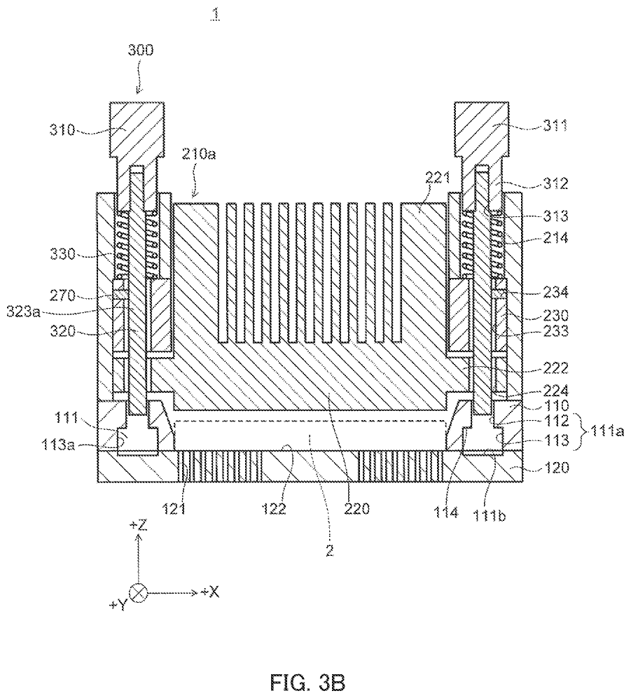

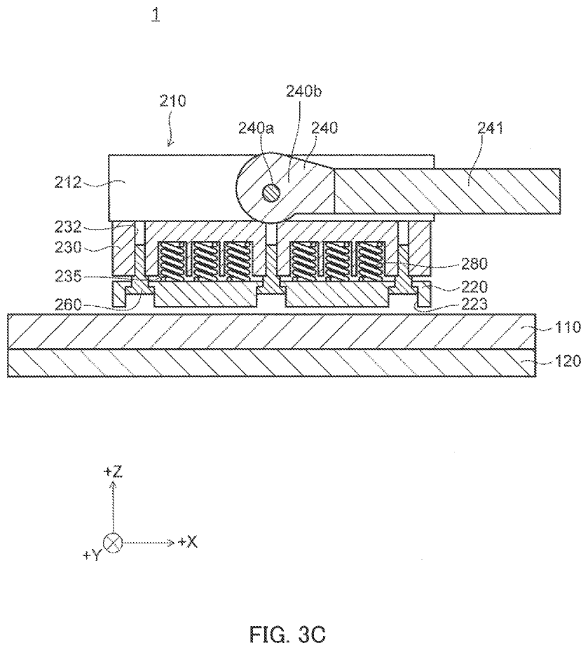

FIG. 1 is a perspective view of socket 1 according to the embodiment. FIG. 2 is a plane view of socket 1 according to the embodiment. FIG. 3A is a cross-sectional view of FIG. 2 taken along 3A to 3A line. FIG. 3B is a cross-sectional view of FIG. 2 taken along 3B to 3B line. FIG. 3C is a cross-sectional view of FIG. 2 taken along 3C to 3C line.

Socket 1 is a device for housing inspected member 2 and electrically connecting between the housed inspected member 2 and a wiring board attached to a lower side of socket 1 (not illustrated). Inspected member 2 is, for example, an electronic component such as an IC-package.

Various inspections are performed on inspected member 2 housed in socket 1 and electrically connected to the wiring board. For example, whether inspected member 2 operates properly is examined in the same environment as an actual usage environment of inspected member 2 or in an environment with a larger load than that with the actual usage environment.

Socket 1 includes socket body 100, cover 200, and locking members 300. FIG. 1 illustrates a state where cover 200 is removed from socket body 100. FIGS. 2 to 3C illustrate a state where cover 200 is placed above socket body 100 without being fixed.

(Socket Body 100)

Socket body 100 includes frame body 110 and bottom plate 120 (exemplary “placing portion”). Frame body 110 defines an outer shape of socket body 100. Frame body 110 includes first part 110a extending in the X direction and second part 110b extending in the X direction in the +Y direction side of first part 110a. Frame body 110 also includes third part 110c extending in the Y direction and connecting between first part 110a and second part 110b, and fourth part 110d extending in the Y direction in the +X direction side of third part 110c and connecting first part 110a and second part 110b.

Holes 111 are provided near the end in a −Y direction and near the end in the +Y direction of third part 110c and also near the end in a −Y direction and near the end in the +Y direction of fourth part 110d. Holes 111 will be described in detail later.

Bottom plate 120 closes, from the lower side, a space surrounded by first part 110a, second part 110b, third part 110c and fourth part 110d. Bottom plate 120 is provided with a plurality of through holes 121 for housing a plurality of contact pins (not illustrated). Inspected member 2 is placed on upper surface 122 of bottom plate 120.

(Hole 111)

With reference to FIG. 3B, holes 111 will be described. As illustrated in FIG. 3B, frame body 110 is provided with holes 111a each vertically penetrating frame body 110. Hole 111a includes small diameter hole 112 that opens in an upper surface of frame body 110 and large diameter hole 113 that is provided on a lower side of small diameter hole 112 and opens in a lower surface of frame body 110.

Small diameter hole 112 is defined by two wall surfaces 112a (see FIG. 1) having planar shapes, respectively, and extending in the Y direction and facing each other, and two wall surfaces 112b (see FIG. 1) each having a curved shape and connecting between wall surfaces 112a. Wall surfaces 112a and wall surfaces 112b are an exemplary “surface defining the small diameter hole”.

Large diameter hole 113 is defined by wall surface 113a having a curved shape. A shape of large diameter hole 113 defined by wall surface 113a is circular in plan view. Further, wall surface 112a, wall surface 112b, and wall surface 113a are connected with each other by connection surface 114 (exemplary “locked portion”).

Recess 111b is provided at a position corresponding to hole 111a in upper surface 122 of bottom plate 120. Hole 111a and recess 111b constitute hole 111 with an open upper part and closed side and bottom parts.

(Cover 200)

Cover 200 is placed on an upper side of socket body 100. Cover 200 includes body portion 210, heat sink 220, and pusher 230. Note that, heat sink 220 and pusher 230 are an exemplary “lifting portion”.

(Body Portion 210)

Body portion 210 defines an outer shape of cover 200. The outer shape of cover 200 defined by body portion 210 is substantially rectangular in plan view. Through hole 210a penetrating in the Z-direction is provided in a central part of body portion 210.

As illustrated in FIG. 3A, through holes 211 penetrating in the Z direction are provided on a central part of the Y direction in the −X direction side and the +X direction side of through hole 210a. Through hole 211 has a stepped shape. That is, through hole 211 includes a large diameter portion that opens in the upper surface of body portion 210 and extends in the −Z direction, a small diameter portion that is located on a lower side of the large diameter portion and extends in the −Z direction, and a step portion for connecting between the large diameter portion and the small diameter portion. Screws 250 (described later) are placed in through holes 211.

As illustrated in FIG. 3B, through holes 214 penetrating in the Z direction are provided near the end in the +Y direction and near the end in −Y direction in the −X direction side and the +X direction side of through hole 210a. Locking member 300 is inserted into through hole 214.

As illustrated in FIG. 3C, in the −Y direction side and the +Y direction side of through hole 210a (see FIG. 3B), groove 212 is provided from the end in the −X direction to the end in the +X direction of body portion 210. As illustrated in FIG. 1, through holes 213 penetrating through grooves 212 are provided on the end face in the −Y direction and the end face in the +Y direction of body portion 210. Lever 240 (exemplary “pressing portion” to be described later) is placed in groove 212. Pivot shaft 240a of lever 240 is pivotally supported by through hole 213.

(Heat Sink 220)

Heat sink 220 is a member which presses inspected member 2 against upper surface 122 of bottom plate 120 by pressing the upper surface of inspected member 2 downward.

Heat sink 220 incudes body portion 221 and flange portion 222.

Body portion 221 is provided with a plurality of projections projecting in the +Z direction. These projections enhance heat dissipation performance of heat sink 220. Flange portion 222 projects from body portion 221 in the X and Y directions.

As illustrated in FIG. 3A, through hole 223 penetrating in the Z direction is provided on a central part of the Y direction in flange portion 222 projecting in the X direction from body portion 221. Through hole 223 has a stepped shape. That is, through hole 223 includes a large diameter portion that opens in a lower surface of flange portion 222 and extends in the +Z direction, a small diameter portion that is located on an upper side of the large diameter portion and extends in the +Z direction, and a step portion for connecting between the large diameter portion and the small diameter portion. Screws 260 (described later) are placed in through holes 223.

As illustrated in FIG. 3B, through holes 224 penetrating in the Z direction are provided near the end in the +Y direction and near the end in −Y direction of flange portion 222 projecting in the X direction from body portion 221. Locking member 300 is inserted into through hole 224.

As illustrated in FIG. 3C, through hole 223 described above is provided on flange portion 222 projecting from body portion 221 in the Y direction.

(Pusher 230)

Pusher 230 is a member that is placed between body portion 210 and heat sink 220 and presses flange portion 222 of heat sink 220 downward. Pusher 230 is a frame-shaped member provided with through hole 231 penetrating in the Z-direction on a central part.

As illustrated in FIG. 3A, screw holes 232 penetrating in the Z direction are provided in central parts of the Y direction in the −X direction side and the +X direction side of through holes 231. Screw hole 232 is screwed with male screw portion 253 of screw 250 (will be described later) and male screw portion 263 of screw 260 (will be described later).

As illustrated in FIG. 3B, through hole 233 penetrating in the Z direction is provided near the end in the +Y direction and −Y direction in the −X direction side and the +X direction side of through hole 231. Locking member 300 is inserted into through hole 233. Further, screw hole 234 penetrating to through hole 233 is provided on the end face in the −X direction and the end face in +X direction of pusher 230. Screw hole 234 is screwed with screw 270 (exemplary “stopper member”).

As illustrated in FIG. 3C, a plurality of holes 235 are provided side by side in the X direction in the −Y direction side and the +Y direction side of through hole 231. Hole 235 is open in a lower side of pusher 230. Coil springs 280 are placed in holes 235.

(Lever 240)

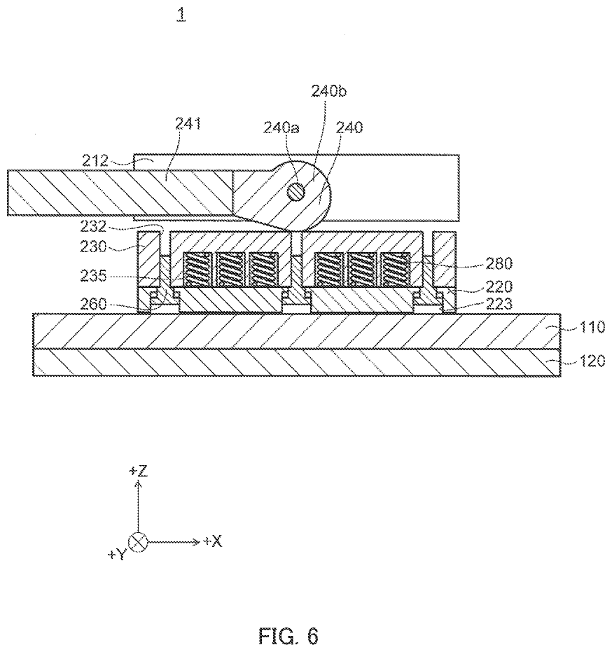

Lever 240 is placed in groove 212 of body portion 210 as described above. Lever 240 includes a pair of cam bodies 240b and handle 241. Lever 240 is attached pivotally about above-described pivot shaft 240a, between a standby position (the position illustrated in FIG. 3C) and an inspection position (the position illustrated in FIG. 6).

By rotating lever 240 from the standby position to the inspection position, cam body 240b pivots about pivot shaft 240a and presses pusher 230 downward.

(Screw 250)

Screw 250 includes columnar portion 252, flange portion 251 provided on an upper side of columnar portion 252, and male screw portion 253 provided on a lower side of columnar portion 252. A diameter of flange portion 251 is slightly smaller than an inner diameter of the large diameter portion of through hole 211. A diameter of columnar portion 252 is slightly smaller than an inner diameter of the small diameter portion of through hole 211.

(Screw 260)

Screw 260 includes columnar portion 262, flange portion 261 provided on a lower side of columnar portion 262, and male screw portion 263 provided on an upper side of columnar portion 262. A diameter of flange portion 261 is slightly smaller than an inner diameter of the large diameter portion of through hole 223. A diameter of columnar portion 262 is slightly smaller than an inner diameter of the small diameter portion of through hole 223.

(Locking Member 300)

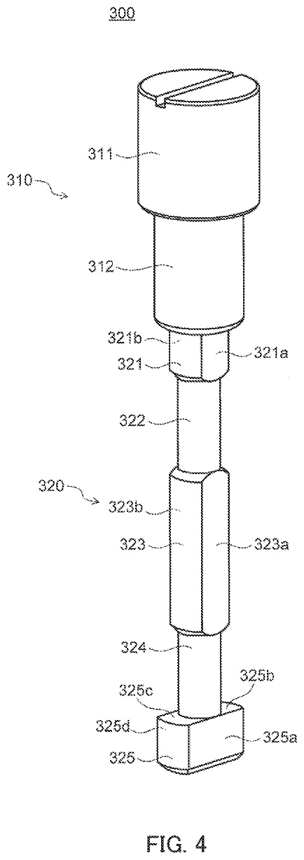

With reference to FIG. 4, locking member 300 will be described. FIG. 4 is a perspective view of locking member 300. Locking member 300 includes holding member 310 and shaft member 320.

Holding member 310 includes holding portion 311 and fixing portion 312. A diameter of holding portion 311 is larger than an inner diameter of a large diameter portion of through hole 214. A diameter of fixing portion 312 is smaller than the inner diameter of the large diameter portion of through hole 214. Fixing portion 312 is provided with female screw portion 313 (see FIG. 3B).

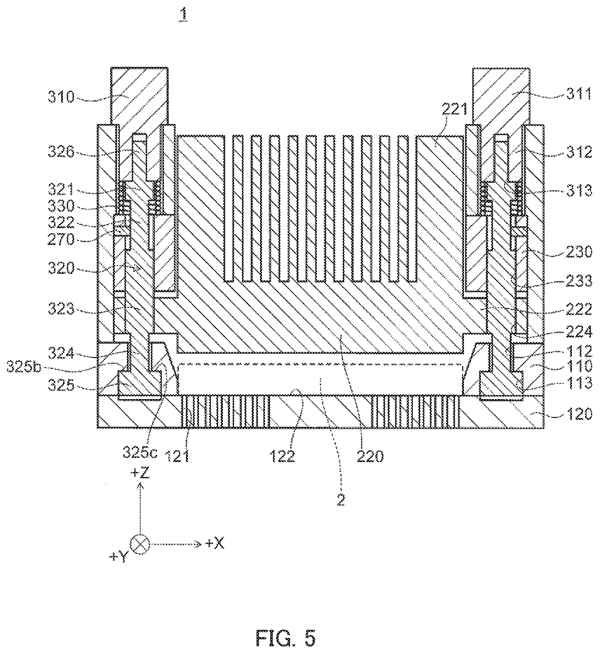

Shaft member 320 includes first large-diameter shaft portion 321, first small-diameter shaft portion 322, second large-diameter shaft portion 323, second small-diameter shaft portion 324, locking portion 325, and male screw portion 326 (see FIG. 5).

First large-diameter shaft portion 321 has a shape in which a side surface of a column is cut out to form planar shapes. First large-diameter shaft portion 321 includes plane portion 321a extending along an axis of shaft member 320 and plane portion 321b facing an opposite side to plane portion 321a. First small-diameter shaft portion 322 is provided on a lower side of first large-diameter shaft portion 321. First small-diameter shaft portion 322 has a columnar shape.

Second large-diameter shaft portion 323 is provided on a lower side of first small-diameter shaft portion 322. Second large-diameter shaft portion 323 has a shape in which a side surface of a column is cut out to form planar shapes. Second large-diameter shaft portion 323 includes plane portion 323a extending along the axis of shaft member 320 and plane portion 323b facing an opposite side to plane portion 323a. Second small-diameter shaft portion 324 is provided on a lower side of second large-diameter shaft portion 323. Second small-diameter shaft portion 324 has a columnar shape.

Locking portion 325 is provided on a lower side of second small-diameter shaft portion 324. Locking portion 325 has a shape in which a side surface of a column is cut out to form planar shapes. Locking portion 325 includes plane portion 325a extending along the axis of shaft member 320 and plane portion 325d facing an opposite side to plane portion 325a.

Further, locking portion 325 includes first locking piece 325b projecting in a first direction perpendicular to the axis of shaft member 320 and second locking piece 325c projecting in a second direction opposite to the first direction. That is, first locking piece 325b and second locking piece 325c extend laterally from shaft member 320 extending vertically. Male screw portion 326 is provided on an upper side of first large-diameter shaft portion 321. Male screw portion 326 is screwed into female screw portion 313 of holding member 310.

A diameter of first large-diameter shaft portion 321 is equal to a diameter of second large-diameter shaft portion 323. A diameter of first small-diameter shaft portion 322 is equal to a diameter of second small-diameter shaft portion 324. A distance from plane portion 321a of first large-diameter shaft portion 321 to plane portion 321b and a distance from plane portion 323a of second large-diameter shaft portion 323 to plane portion 323b are equal to the diameter of first small-diameter shaft portion 322 (i.e., equal to the diameter of second small-diameter shaft portion 324). A distance from plane portion 325a of locking portion 325 to plane portion 325d is slightly shorter than a distance between opposing wall surfaces 112b of small diameter hole 112.

(Operational Effects)

As described above, FIGS. 3A to 3C indicate a state in which cover 200 is not fixed with respect to socket body 100. In the states illustrated in FIGS. 3A to 3C, lever 240 is in the standby position and no downward pressing force is applied to pusher 230.

As illustrated in FIG. 3A, coil spring 290 is placed in through hole 211 of body portion 210. Coil spring 290 energizes pusher 230 upward through screw 250. An upper surface of pusher 230 abuts on body portion 210.

As illustrated in FIG. 3C, coil springs 280 are placed in holes 235 of pusher 230. Coil spring 280 energizes heat sink 220 downward. Downward movement of heat sink 220 is restricted by flange portion 261 of screw 260 abutting on the step portion of through hole 223. A lower surface of pusher 230 and an upper surface of flange portion 222 of heat sink 220 face each other through a gap.

As illustrated in FIG. 3B, coil springs 330 are placed in through holes 214 of body portion 210. Coil spring 330 energizes locking member 300 upward. Note that, upward movement of locking member 300 is restricted by locking portion 325 of locking member 300 abutting on the lower surface of flange portion 222 of heat sink 220.

In the state illustrated in FIG. 3B, the tip of screw 270 faces plane portion 323a of second large-diameter shaft portion 323 of locking member 300. Moreover, a vertical position of locking portion 325 of locking member 300 corresponds to a position of small diameter hole 112 in hole 111. Thus, in this state, even when locking member 300 is made to rotate about its own axis, the rotation of locking member 300 is restricted by screw 270 abutting on plane portion 323a or by plane portion 325a of locking portion 325 abutting on wall surface 112a of small diameter hole 112.

When locking member 300 is pushed down against an energizing force of coil spring 330 from the state illustrated in FIG. 3B, the tip of screw 270 faces first small-diameter shaft portion 322. Further, the vertical position of locking portion 325 matches the position of large diameter hole 113 in hole 111. In this state, locking member 300 can rotate about its own axis.

FIG. 5 indicates a state in which cover 200 is fixed with respect to socket body 100. As illustrated in FIG. 5, when a downward pressing force to locking member 300 is released in a state where locking member 300 is rotated about its own axis, and both first locking piece 325b and second locking piece 325c of locking portion 325 face connection surface 114, locking member 300 is made to move upward by the energizing force of coil spring 330.

At this time, first locking piece 325b and second locking piece 325c abut on connection surface 114, and thus press against connection surface 114.

As described above, cover 200 can be fixed with respect to socket body 100 by rotating locking member 300 about its own axis and engaging locking pieces 325b and 325c with connection surface 114.

When lever 240 is turned from the standby position to the inspection position in a state where cover 200 is fixed with respect to socket body 100, pusher 230 and heat sink 220 are pressed downward. Moreover, inspected member 2 is pressed by pusher 230 toward upper surface 122 of bottom plate 120 in socket body 100 (i.e., the state in FIG. 6).

At this time, between locking portion 325 and connection surface 114, a reaction force is applied against the force that cam body 240b pushes pusher 230 and heat sink 220 downward. In the present embodiment, since there is a plurality of locking members 300, and since each locking member 300 includes two locking pieces (first locking piece 325b and second locking piece 325c), such a reaction force can be shared among a plurality of places. Thus, it is possible to suppress an increase in size of locking member 300.

Further, locking members 300 are each inserted into through holes (through hole 214, through hole 233 and through hole 224) provided in cover 200. Thus, as compared with the case of providing a latch on an outer peripheral part of cover 200, it is possible to suppress an increase in size of cover 200.

Further, locking portion 325 of locking member 300 is configured to enter hole 111 provided in frame body 110 of socket body 100. Thus, as compared with the case of providing an engaged portion on an outer peripheral part of socket body 100, it is possible to suppress an increase in size of socket body 100.

Further, holes 111 provided on third part 110c and fourth part 110d of frame body 110 include small diameter hole 112 and large diameter hole 113. In addition, small diameter hole 112 is defined by wall surfaces 112a extending in an extending direction of third part 110c and fourth part 110d and facing each other, and wall surfaces 112b each connecting between wall surfaces 112a. As a result, the length in a direction perpendicular to the extending direction in third part 110c and fourth part 110d can be suppressed, and thus, it is possible to suppress an increase in size of socket body 100.

As described above, socket 1 according to the present embodiment includes: socket body 100 housing inspected member 2 therein and including a portion to be locked (hereinafter, referred to as “locked portion”) (connection surface 114); cover 200 placed on an upper side of socket body 100; and locking member 300 which is supported by cover 200 and has shaft portion 320 extending in the vertical direction and locking portion 325 extending in a direction intersecting the vertical direction. In socket 1, cover 200 is fixed with respect to socket body 100 by rotating locking member 300 about its own axis to engage locking portion 325 with locked portion 114.

Rotating locking member 300 about its own axis enables to engage locking portion 325 with locked portion 114; thus, as compared with the case of using a latch provided with an engaging portion on one side, an engagement operation can be performed within a small space. Thus, it is possible to fix cover 200 with respect to socket body 100 without increasing the size of socket 1.

In the above embodiment, a description has been given with an example in which a first locking piece and a second locking piece extending in a direction intersecting the extending direction of a shaft portion of a locking member are provided; however, the present disclosure is not limited this. The number of locking pieces may be one.

In the above embodiment, a description has been given with an example in which a spring for energizing the locking member upward between a cover and the locking member is provided; however, the present disclosure is not limited this. The spring for energizing the locking member upward may be omitted. Note that, in a case where the locking member is energized upward by the spring, an upper end of the locking member largely projects from an upper surface of the cover when the locking portion is not engaged with a locked portion, and thus, it is possible to easily distinguish whether the locking portion and the locked portion are engaged with each other.

In the above embodiment, a description has been given with an example in which a stopper member for restricting rotation of the locking member is provided; however, the present disclosure is not limited this. The stopper member may be omitted. Note that, providing the stopper member can prevent the locking member from rotating about its own axis before the cover is placed on the upper side of the socket body. In other words, malfunction of the locking member can be prevented. Thus, it is possible to enhance workability of inspection.

Further, in the above embodiment, a description has been given with an example in which a cam body is used for pressing the cover toward the socket body; however, the present disclosure is not limited this. A publically known method can be appropriately employed as a method for pressing the cover against the socket body.

This application claims priority based on Japanese Patent Application No. 2018-230028, filed on Dec. 7, 2018, the entire contents of which including the specification and the drawings are incorporated herein by reference.

### INDUSTRIAL APPLICABILITY

The present disclosure can be widely utilized for inspecting electrical characteristics of an inspected member.

### REFERENCE SIGNS LIST

1 Socket
2 Inspected member
100 Socket body
110 Frame body
110a First part
110b Second part
110c Third part
110d Fourth part
111 Hole
111a Hole
111b Recess
112 Small diameter hole
112a Wall surface
112b Wall surface
113 Large diameter hole
113a Wall surface
114 Connection surface (locked portion)
120 Bottom plate
121 Through hole
122 Upper surface
200 Cover
210 Body portion
210a Through hole
211 Through hole
212 Groove
213 Through hole
214 Through hole
220 Heat sink
221 Body portion
222 Flange portion
223 Through hole
224 Through hole
230 Pusher
231 Through hole
232 Screw hole
233 Through hole
234 Screw hole
235 Hole
240 Lever
240a Pivot shaft
240b Cam body
241 Handle
250 Screw
251 Flange portion
252 Columnar portion
253 Male screw portion
260 Screw
261 Flange portion
262 Columnar portion
263 Male screw portion
270 Screw
280 Coil spring
290 Coil spring
300 Locking member
310 Holding member
311 Holding portion
312 Fixing portion
313 Female screw portion
320 Shaft member (shaft portion)
321 First large-diameter shaft portion
321a Plane portion
321b Plane portion
322 First small-diameter shaft portion
323 Second large-diameter shaft portion
323a Plane portion
323b Plane portion
324 Second small-diameter shaft portion
325 Locking portion
325a Plane portion
325b First locking piece
325c Second locking piece
325d Plane portion
326 Male screw portion
330 Coil spring

What is claim is:

1. A socket, comprising:
a socket body in which an inspected member is housed and which includes a locked portion;
a cover placed on an upper side of the socket body; and
a locking member which is supported by the cover and includes a shaft portion extending in a vertical direction and a locking portion extending in a direction intersecting the vertical direction, wherein
the cover is fixed with respect to the socket body by rotation of the locking member about its own axis to engage with the locked portion.

2. The socket according to claim 1, wherein
the cover includes a through hole penetrating in the vertical direction, and
the locking portion is inserted into the through hole.

3. The socket according to claim 1, wherein
the locking portion includes a first locking portion and a second locking portion each extending laterally from the shaft portion.

4. The socket according to claim 1, wherein
the socket body incudes:
a frame body including a hole which allows the locking portion to enter the hole; and
a placing portion which is surrounded by the frame body and on which the inspected member is placed, and
the hole includes a small diameter hole and a large diameter hole which is connected to the small diameter hole, and
a surface which connects between a surface defining the small diameter hole and a surface defining the large diameter hole functions as the locked portion.

5. The socket according to claim 1, further comprising:
a spring which is placed between the cover and the locking portion and energizes the locking portion upward, and wherein
the locking portion presses against the locked portion with an energizing force of the spring.

6. The socket according to claim 1, wherein
the shaft portion includes a small diameter portion and a large diameter portion provided on a lower surface of the small diameter portion, and
the cover includes a stopper member which allows, when the cover faces the small diameter portion, rotation of the locking portion and which restricts, when the cover faces the large diameter portion, the rotation of the locking portion by abutting on a cut surface provided in the large diameter portion.
